(19) United States
(12) Patent Application Publication
(10) Pub. No.: US 2025/0201645 A1
(43) Pub. Date: Jun. 19, 2025

(54) FABRICATING PACKAGES WITH DUMMY DIES HAVING A CONSTRUCTION THAT MIMICS WARPAGE OF THE OTHER COMPONENTS INCLUDED IN THE PACKAGE

(71) Applicant: Microsoft Technology Licensing, LLC, Redmond, WA (US)

(72) Inventors: Rahul AGARWAL, Livermore, CA (US); Jon Thomas WOODYARD, Livermore, CA (US); Cliff C. LEE, Bellevue, WA (US); Sriram SRINIVASAN, Chandler, AZ (US)

(21) Appl. No.: 18/538,043

(22) Filed: Dec. 13, 2023

(51) Int. Cl. H01L 23/31; H01L 21/56; H01L 23/00; H01L 23/498; H01L 25/00; H01L 25/065; H01L 25/16

(52) U.S. Cl. CPC H01L 23/3128; H01L 21/565; H01L 23/49816; H01L 24/13; H01L 24/16; H01L 25/0657; H01L 25/16; H01L 25/50; H01L 2224/13023; H01L 2224/16155

(57) ABSTRACT

Methods for fabricating packages with dummy dies having a construction that mimics warpage of the other components included in the package are described. A method for fabricating a package with a floor plan having sections for placement of components includes arranging a first component in a first section of the floor plan and arranging a second component in a second section of the floor plan, where each of the first component and the second component comprises active circuitry for providing at least one of compute, storage, or communication functionality. The method further includes forming a dummy die having a construction that mimics warpage of at least one of the first component or the second component. The method further includes arranging the dummy die in an unoccupied section of the floor plan for the package.

### BACKGROUND

Increasingly, computing, storage, and communication systems include dies and other components that are packaged in the form of 2.5 packages. As an example, chiplets or dies may be stacked side by side on a passive interposer or an active interposer to form a 2.5D package. Alternatively, high-bandwidth memory (HBM) may be stacked side by side with a system on chip (SoC) on an interposer. Multiple logic dies may also be stacked on top of each other. In another arrangement, a mix of logic dies and memory dies are used and they may use an interposer. Such examples of various components may be packaged in the form of a 2.5D package.

Because of the different configurations associated with the 2.5D packages, dummy dies may be needed. While the presence of the dummy dies helps, because of a coefficient of thermal expansion (CTE) mismatch between the dummy dies and the other components and material included in the 2.5D package, warpage and reliability issues can arise. As an example, cracks may be formed in the area between a dummy die and another component (e.g., an SoC chip) or cracks may be formed in the corners of the 2.5D package.

Accordingly, there is a need for methods for making improved packages with dummy dies.

### SUMMARY

In one example, the present disclosure relates to a method for fabricating a package with a floor plan having sections for placement of components. The method includes arranging a first component in a first section of the floor plan and arranging a second component in a second section of the floor plan, where each of the first component and the second component comprises active circuitry for providing at least one of compute, storage, or communication functionality.

The method may further include forming a dummy die having a construction that mimics warpage of at least one of the first component or the second component. The method may further include arranging the dummy die in an unoccupied section of the floor plan for the package.

In another example, the present disclosure relates to a method for fabricating a package with a floor plan having sections for placement of components. The method may include arranging a first component in a first section of the floor plan and arranging a second component in a second section of the floor plan, wherein each of the first component and the second component comprises active circuitry for providing at least one of compute, storage, or communication functionality.

The method may further include forming a dummy die having a predetermined silicon to mold ratio that is selected to reduce warpage of the package. The method may further include arranging the dummy die in an unoccupied section of the floor plan for the package.

In yet another example, the present disclosure relates to a 2.5 dimension (2.5D) package comprising an interposer with a floor plan for arranging components associated with the 2.5D package. The 2.5D package may further include a first component arranged in a first section of the floor plan.

The 2.5D package may further include a second component arranged in a second section of the floor plan, wherein each of the first component and the second component comprises active circuitry for providing at least one of compute, storage, or communication functionality, and wherein the first component and the second component are coupled via the interposer. The 2.5D package may further include a plurality of dummy dies, arranged in any unoccupied sections of the floor plan, where each of the plurality of dummy dies has a construction that mimics warpage of at least one of the first component or the second component.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows a view of a fabrication stage of a dummy die for a 2.5D package in accordance with one example;

FIG. 2 shows a view of a fabrication stage of a dummy die for a 2.5D package in accordance with one example;

FIG. 3 shows a view of a fabrication stage of a dummy die for a 2.5D package in accordance with one example;

FIG. 4 shows two alternative views of a fabrication stage of a dummy die for a 2.5D package in accordance with one example;

FIG. 5 shows example dummy dies with different silicon to mold ratios for use with 2.5D packages;

FIG. 6 shows a view of a fabrication stage of a dummy die for a 2.5D package in accordance with another example;

FIG. 7 shows a view of a fabrication stage of a dummy die for a 2.5D package in accordance with another example;

FIG. 8 shows a view of a fabrication stage of a dummy die for a 2.5D package in accordance with another example;

FIG. 9 shows a view of a fabrication stage of a dummy die for a 2.5D package in accordance with another example;

FIG. 10 shows two alternative views of a fabrication stage of a dummy die for a 2.5D package in accordance with one example;

FIG. 11 shows and top view of a 2.5D package with unoccupied sections and the floor plan of the same 2.5D package with dummy dies arranged in the unoccupied sections;

FIG. 12 shows a side view of a 2.5D package along a cross-section of the 2.5D package of FIG. 11;

FIG. 13 shows a flow chart of a method for fabricating a package with a floor plan having sections for placement of components in accordance with one example; and

FIG. 14 shows a flow chart of another method for fabricating a package with a floor plan having sections for placement of components in accordance with one example.

### DETAILED DESCRIPTION

Examples described in this disclosure relate to fabricating packages with dummy dies having a construction that mimics warpage of the other components and material included in the package. Because of the different configurations associated with the 2.5 dimension (2.5D) packages, dummy dies may be needed. While the presence of the dummy dies helps, because of a coefficient of thermal expansion (CTE) mismatch between the dummy dies and the other components included in the 2.5D package, warpage and reliability issues can arise. As an example, cracks may be formed in the area between a dummy die and another component (e.g., an SoC chip) or cracks may be formed in the corners of the 2.5D package. These cracks are formed because of the different ways in which stresses develop as a function of the CTE and the modulus of elasticity associated with different dies.

Examples described herein use dummy dies as part of the 2.5D package where the CTE and the modulus of elasticity for the dummy dies is modulated by controlling the silicon to mold ratio within the dummy die itself. As an example, assume a case of a 2.5D package that includes one or more high bandwidth memory (HBM) dies, each of which includes stacked memory die along with a logic die, and the package requires dummy dies to balance the floor plan associated with the package. A traditional dummy die with silicon only will have a different response to thermal expansion since the dummy die has a different CTE/modulus relationship from the HBM modules. In the present disclosure, methods are described to enable 2.5D packages that include dummy dies with carefully modulated CTE/modulus of elasticity (e.g., based on the silicon to mold ratio of such dummy dies). By using appropriately modulated dummy dies in this respect both warpage and cracks caused by the warpage can be minimized. The 2.5D packages may be fan-out wafer level packages or chip-on-wafer-on-substrate (CoWoS) packages. Fan-out wafer level packages may have structures like fan-out multiple chip module (FOMCM) or fan-out embedded bridge die (FOEB). As part of these packages, not only HBM modules could be combined with the SoC die, but other die forms, such as chiplets, may also be combined. The dies or chiplets may also comprise central processing units (CPUs), application specific integrated circuits (ASICs), graphical processing units (GPUs), field programmable gate arrays (FPGAs), microcontrollers, I/O circuits, SRAMs, flash memory, Ethernet PHYs, or other silicon IP.

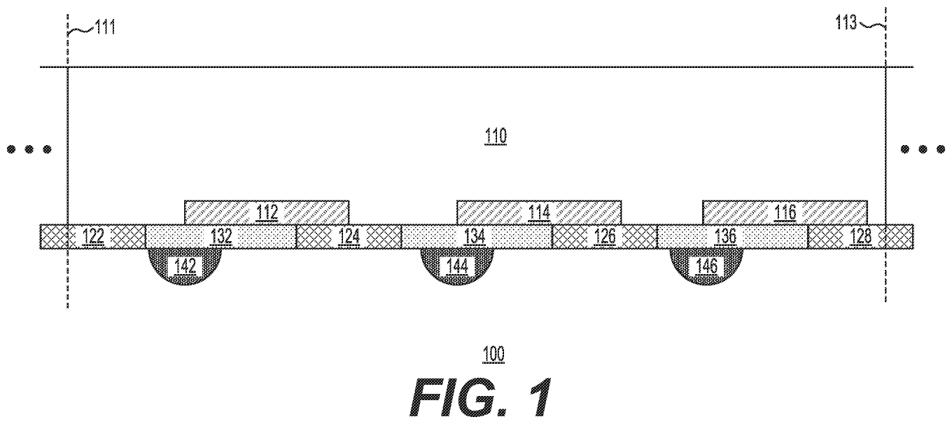

FIG. 1 shows a view of a fabrication stage of a dummy die 100 for a 2.5D package in accordance with one example. Dummy die 100 includes a silicon portion 110. As shown during this fabrication stage, dummy die 100 is formed by separating individual dies along saw lines (e.g., saw lines 111 and 113) from a common wafer structure. During this fabrication stage, dummy die 100 further includes metal layer portions 112, 114, and 116. In one example, metal layer portions 112, 114, and 116 comprise a conductive material, such as copper. Dummy die 100 further includes passivation layer portions 122, 124, 126, and 128. Passivation layer portions 122, 124, 126, and 128 are the remaining portions of the passivation layer, which had been formed on the entire surface of the wafer to protect the entire surface of the wafer. In one example, the passivation layer may be comprised of silicon nitride or silicon oxide.

With continued reference to FIG. 1, dummy die 100 further includes contact pads 132, 134, and 136, which may comprise aluminum. Contact pads 132, 134, and 136 relate to the sites on which interconnection structures, such as bumps, may be formed. As an example, dummy die 100 includes bumps 142, 144, and 146 that have been formed on respective contact pads. Although FIG. 1 shows dummy die 100 with a certain number of layers and components arranged in a certain manner there could be more or fewer number of layers or components, which could be arranged differently.

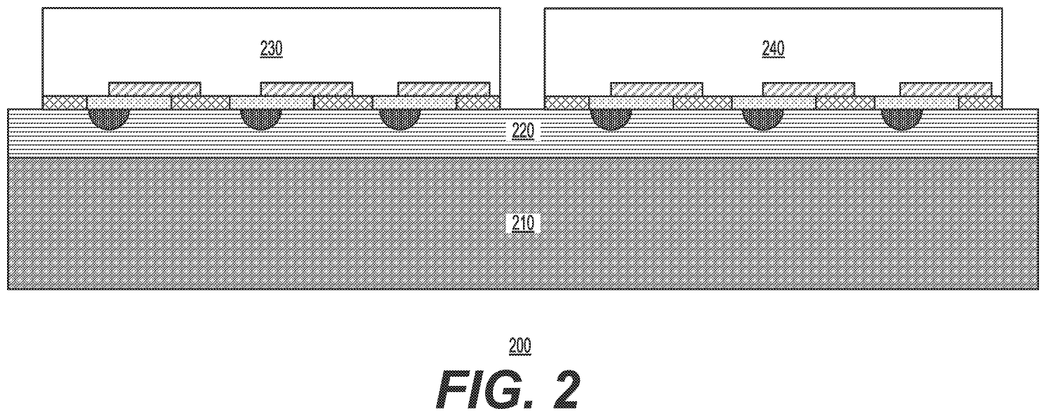

FIG. 2 shows a view 200 of a fabrication stage of a dummy die for a 2.5D package in accordance with one example. Unless indicated otherwise, the same or similar layers and components that are shown in FIG. 2 are referred to using the same reference numbers as used in FIG. 1. At this stage of fabrication multiple dummy dies 230 and 240 are processed using a carrier wafer 210. Each of dummy dies 230 and 240 is similar to dummy die 100 and includes the various layers and components described earlier with respect to FIG. 1. Glue material 220, which is later removed, is present between the top surface of carrier wafer 210 and the two dummy dies. Although FIG. 2 shows dummy die 230 and dummy die 240 arranged in a certain manner on carrier wafer 210, these dummy dies could be arranged differently.

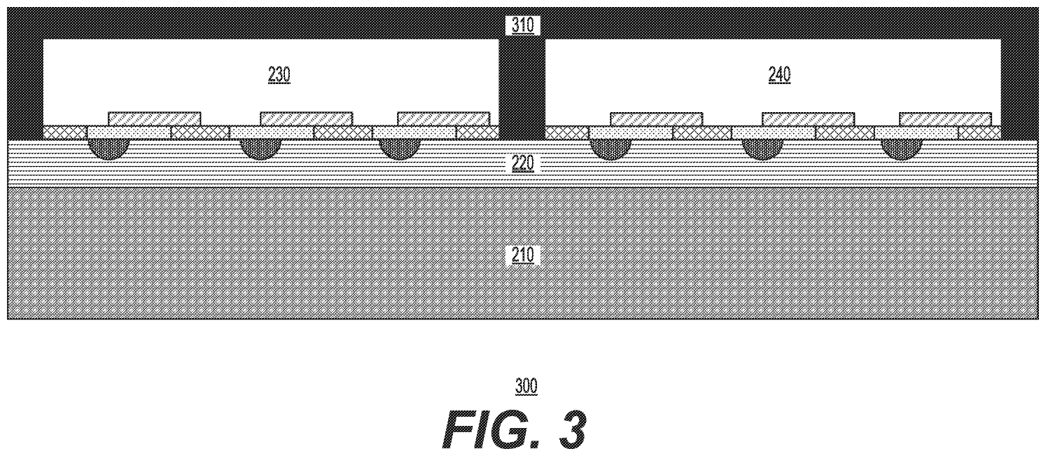

FIG. 3 shows a view 300 of a fabrication stage of a dummy die for a 2.5D package in accordance with one example. Unless indicated otherwise, the same or similar layers and components that are shown in FIG. 3 are referred to using the same reference numbers as used in the previous figures (e.g., FIGS. 1 and 2). As part of this fabrication stage, the dummy dies 230 and 240, arranged on a carrier wafer 210, are over-molded using a mold compound 310 (e.g., an epoxy mold compound). As a result, each of dummy dies 230 and 240 include both a silicon portion (e.g., similar to silicon portion 110 of FIG. 1) and a mold compound.

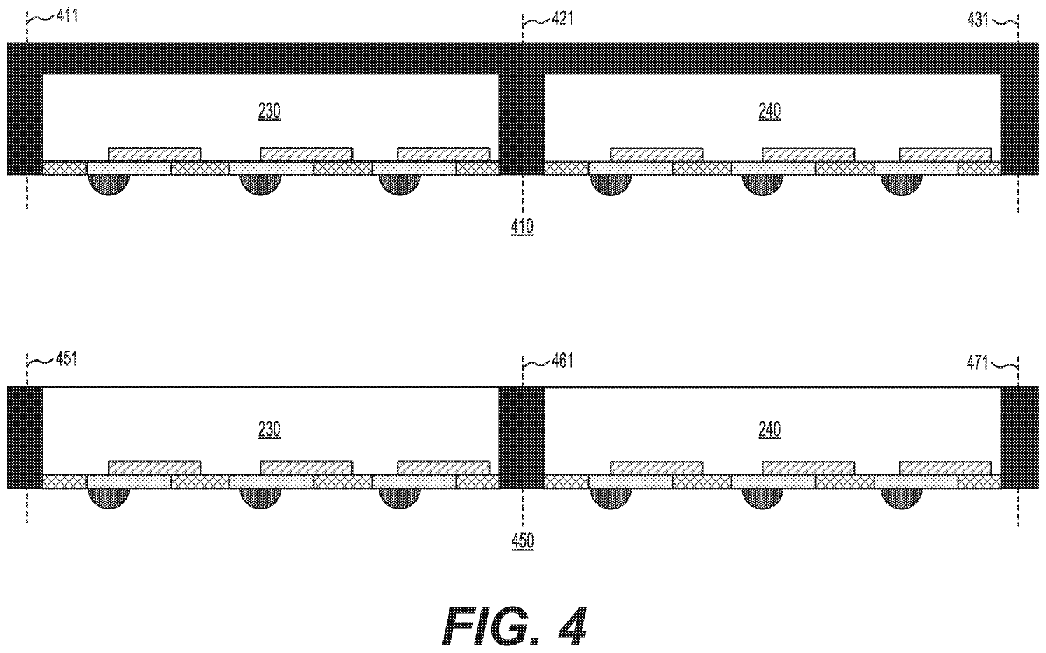

FIG. 4 shows two alternative views 410 and 450 of a fabrication stage of a dummy die for a 2.5D package in accordance with one example. Unless indicated otherwise, the same or similar layers and components that are shown in FIG. 4 are referred to using the same reference numbers as used in the previous figures (e.g., FIGS. 1, 2, and 3). As shown in view 410, during this fabrication stage, dummy dies 230 and 240 are separated into individual dies by sawing along saw lines 411, 421, and 431. The sawing step results in two separated dummy dies with mold compound on five sides of each of the dummy dies.

With continued reference to FIG. 4, in view 450, prior to separating the dummy dies, the mold compound on top of the dummy dies is removed via grinding. The grinding itself may be accomplished using processes, such as mechanical grinding or chemical mechanical polishing. Alternatively, the mold compound on the top of the dummy dies may be sawed off. After the mold compound from the top of the dummy dies 230 and 240 has been removed, these dummy dies are separated by sawing along saw lines 451, 461, and 471. The sawing step results in two separated dummy dies with mold compound on four sides of each of the dummy dies. The CTE and the modulus of elasticity for the dummy dies (e.g., the dummy dies shown in views 410 and 450) is modulated by controlling the silicon to mold ratio within the dummy die itself. Dummy dies can have carefully modulated CTE/modulus of elasticity by controlling the silicon to mold ratio of such dummy dies. As an example, view 410 shows mold on five sides of the silicon portion as part of the dummy dies 230 and 240, whereas view 450 shows mold on only four sides of the silicon portion as part of the dummy dies 230 and 240. By using appropriately modulated dummy dies in this respect both warpage and cracks caused by the warpage can be minimized.

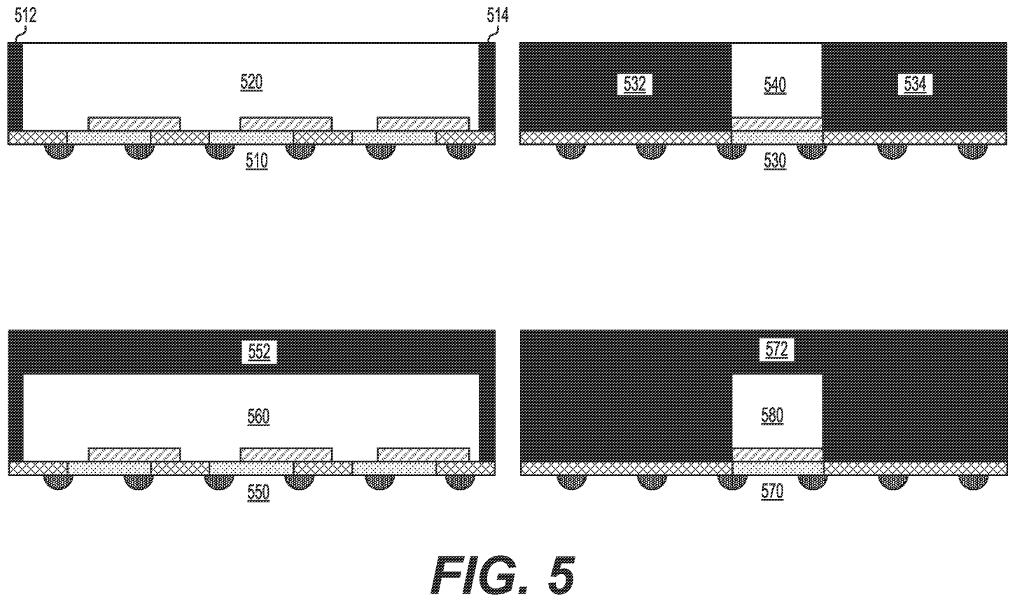

FIG. 5 shows example dummy dies 510, 530, 550, and 570 with different silicon to mold ratios for use with 2.5D packages. Unless indicated otherwise, the same or similar layers and components that are shown in FIG. 5 are referred to using the same reference numbers as used in the previous figures (e.g., FIGS. 1-4). Dummy dies 510, 530, 550, and 570 (each of which can be fabricated using the process flow described earlier with respect to FIGS. 1-4) illustrate the CTE to modulus of elasticity modulation of these dummy dies by selecting the silicon to mold ratio. As an example, dummy die 510 shows mold portions 512 and 514 on four sides of silicon portion 520. Similarly, although dummy die 530 shows mold portions 532 and 534 on four sides of silicon portion 540, the silicon to mold ratio is very different. Thus, while dummy die 510 shows a high silicon to mold ratio, dummy die 530 shows a low silicon to mold ratio.

As another example, dummy die 550 shows mold portion 552 on five sides of silicon portion 560. Similarly, although dummy die 570 shows mold portion 572 on five sides of silicon portion 580, the silicon to mold ratio is very different. Thus, while dummy die 550 shows a high silicon to mold ratio, dummy die 570 shows a low silicon to mold ratio. As explained earlier, by using appropriately modulated dummy dies in this respect both warpage and cracks caused by the warpage in a 2.5D package can be minimized.

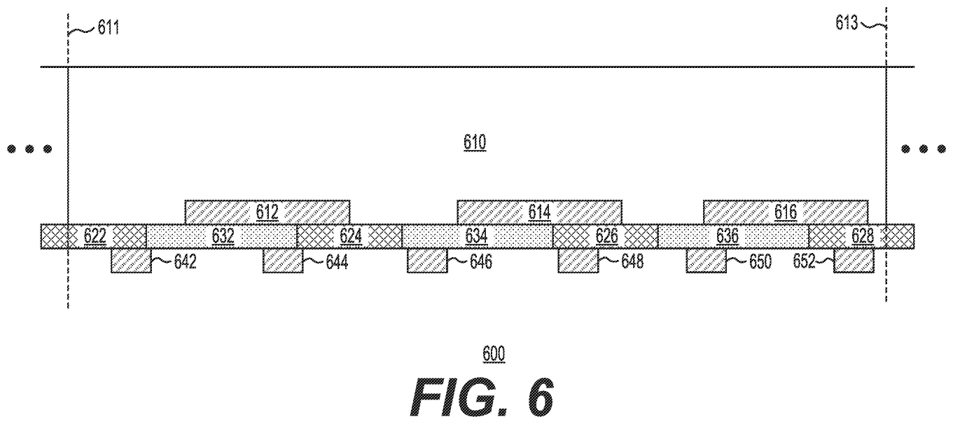

FIG. 6 shows a view of a fabrication stage of a dummy die 600 for a 2.5D package in accordance with one example. As part of this fabrication process, the dummy dies are fabricated in a “dead bug” orientation (electrical contacts (e.g., bumps) are facing up). This is the opposite orientation of the electrical contacts shown with respect to the process flow described earlier with respect to FIGS. 1-4. Dummy die 600 includes a silicon portion 610. As shown during this fabrication stage, dummy die 600 is formed by separating individual dies along saw lines (e.g., saw lines 611 and 613) from a common wafer structure. During this fabrication stage, dummy die 600 further includes metal layer portions 612, 614, and 616. In one example, metal layer portions 612, 614, and 616 comprise a conductive material, such as copper. Dummy die 600 further includes passivation layer portions 622, 624, 626, and 628. As before, passivation layer portions 622, 624, 626, and 628 are the remaining portions of the passivation layer, which had been formed on the entire surface of the wafer to protect the entire surface of the wafer. In one example, the passivation layer may be comprised of silicon nitride or silicon oxide.

With continued reference to FIG. 6, dummy die 600 further includes contact pads 632, 634, and 636, which may comprise aluminum. Dummy die 600 includes metal layer portions 642, 644, 646, 648, 650, and 652. Metal layer portions 642, 644, 646, 648, 650, and 652 comprise a metal (e.g., plated copper). As described further below, bumps can be formed on metal layer portions 642, 644, 646, 648, 650, and 652. Although FIG. 6 shows dummy die 600 with a certain number of layers and components arranged in a certain manner there could be more or fewer number of layers or components, which could be arranged differently.

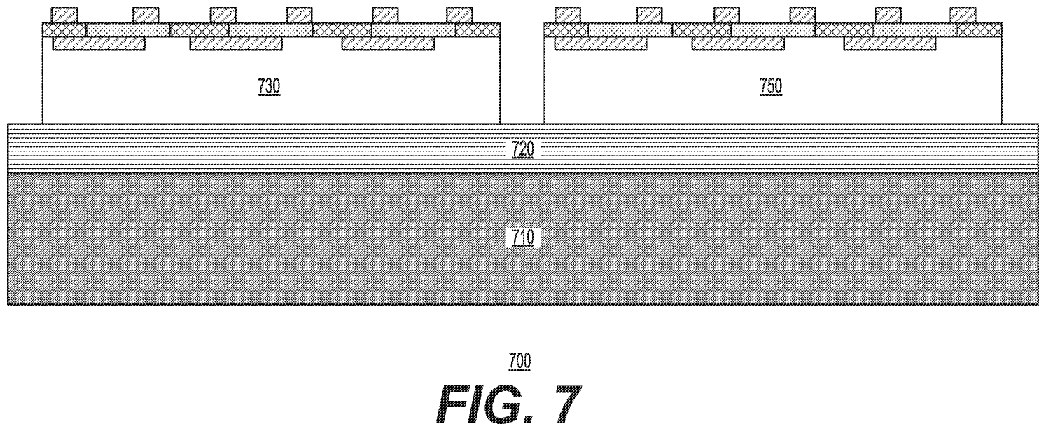

FIG. 7 shows a view 700 of a fabrication stage of a dummy die for a 2.5D package in accordance with one example. Unless indicated otherwise, the same or similar layers and components that are shown in FIG. 7 are referred to using the same reference numbers as used in FIG. 6. At this stage of fabrication multiple dummy dies 730 and 750 are processed using a carrier wafer 710. Each of dummy dies 730 and 750 is similar to dummy die 600 and includes the various layers and components described earlier with respect to FIG. 6. Glue material 720, which is later removed, is present between the top surface of carrier wafer 710 and the two dummy dies. Although FIG. 7 shows dummy die 730 and dummy die 750 arranged in a certain manner on carrier wafer 710, these dummy dies could be arranged differently.

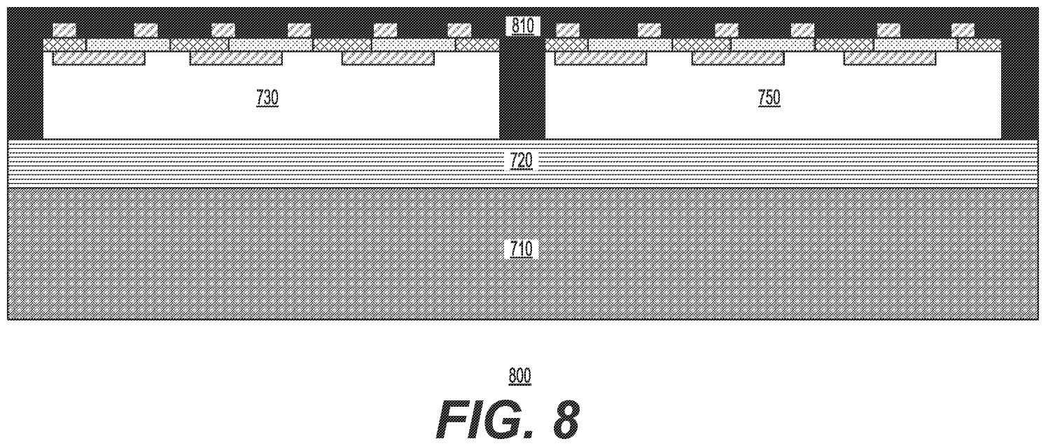

FIG. 8 shows a view 800 of a fabrication stage of a dummy die for a 2.5D package in accordance with one example. Unless indicated otherwise, the same or similar layers and components that are shown in FIG. 8 are referred to using the same reference numbers as used in the previous figures (e.g., FIGS. 6 and 7). As part of this fabrication stage, the dummy dies 730 and 750, arranged on a carrier wafer 710, are over-molded using a mold compound 810 (e.g., an epoxy mold compound). As a result, each of dummy dies 730 and 750 include both a silicon portion (e.g., similar to silicon portion 610 of FIG. 1) and a mold compound.

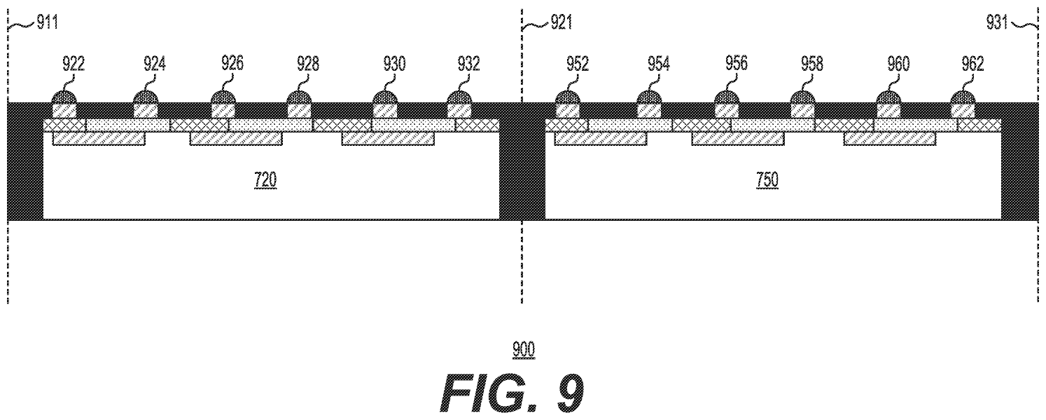

FIG. 9 shows a view 900 of a fabrication stage of a dummy die for a 2.5D package in accordance with one example. Unless indicated otherwise, the same or similar layers and components that are shown in FIG. 9 are referred to using the same reference numbers as used in the previous figures (e.g., FIGS. 6, 7, and 8). As shown in view 900, during this fabrication stage, with respect to dummy die 730, solder caps 922, 924, 926, 928, 930, and 932 are formed over respective metal layer portions 642, 644, 646, 648, 650, and 652 described earlier with respect to dummy die 600 of FIG. 6. In addition, during this fabrication stage, with respect to dummy die 750, solder caps 952, 954, 956, 958, 960, and 962 are formed over respective metal layer portions 642, 644, 646, 648, 650, and 652 described earlier with respect to dummy die 600 of FIG. 6. Although bump formation on dummy dies is described using certain steps above, other processes may also be used. As an example, although solder caps are shown as part of the bumps, these solder caps may not be required. As an example, in a manufacturing process where the metal layers for the bumps are formed using gold (Au), then the solder caps may be omitted as part of the process. Next, dummy dies 730 and 750 are separated into individual dies by sawing along saw lines 911, 921, and 931. The sawing step results in two separated dummy dies with mold compound on five sides of each of the dummy dies.

The CTE and the modulus of elasticity for the dummy dies 730 and 750 is modulated by controlling the silicon to mold ratio within the dummy die itself. Dummy dies can have carefully modulated CTE/modulus of elasticity by controlling the silicon to mold ratio of such dummy dies. By using appropriately modulated dummy dies in this respect both warpage and cracks caused by the warpage can be minimized.

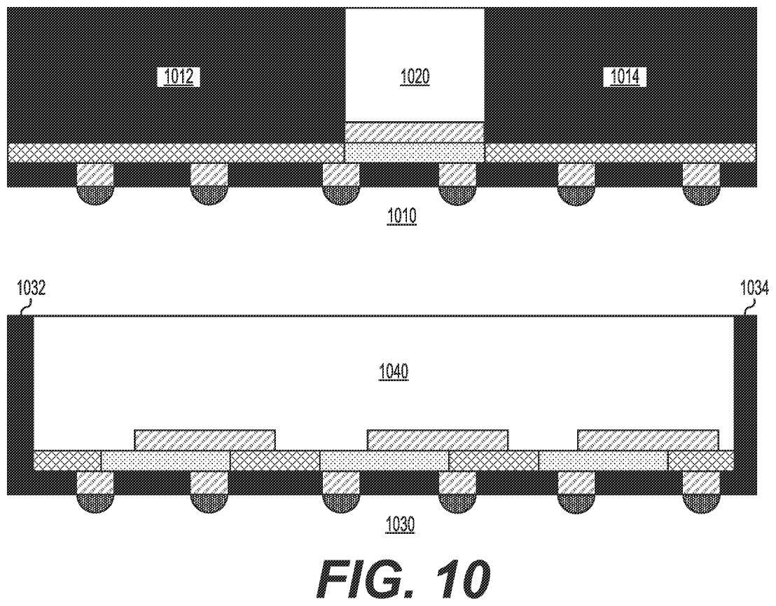

FIG. 10 shows example dummy dies 1010 and 1030 with different silicon to mold ratios for use with 2.5D packages. Unless indicated otherwise, the same or similar layers and components that are shown in FIG. 10 are referred to using the same reference numbers as used in the previous figures (e.g., FIGS. 1-4). Dummy dies 1010 and 1030 (each of which can be fabricated using the process flow described earlier with respect to FIGS. 6-9) illustrate the CTE to modulus of elasticity modulation of these dummy dies by selecting the silicon to mold ratio. As an example, dummy die 1010 has mold portions 1012 and 1014 on four sides (additional mold portions on two other sides are not visible in FIG. 10) of silicon portion 1020. Similarly, although dummy die 1030 has mold portions 1032 and 1034 on four sides (additional mold portions on two other sides are not visible in FIG. 10) of silicon portion 1040, the silicon to mold ratio is very different. Thus, while dummy die 1010 shows a low silicon to mold ratio, dummy die 1030 shows a high silicon to mold ratio. As explained earlier, by using appropriately modulated dummy dies in this respect both warpage and cracks caused by the warpage in a 2.5D package can be minimized. As an example, although not shown in FIG. 10, mold could be formed on the top surface of silicon portions of each of the dummy dies shown in FIG. 10.

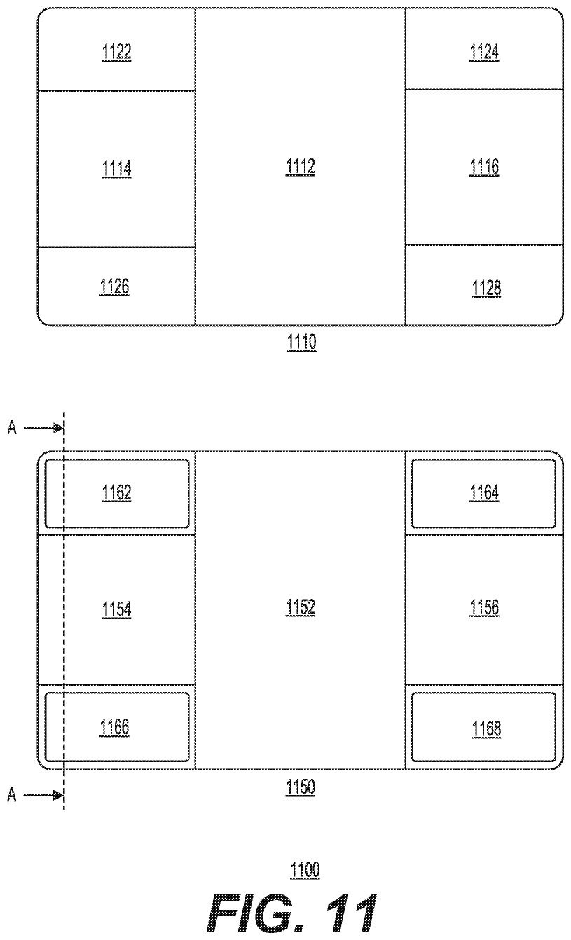

FIG. 11 shows the floor plan 1110 of a 2.5D package with unoccupied sections and top view 1150 of the same 2.5D package with dummy dies arranged in the unoccupied sections. Floor plan 1110 shows a system on chip (SoC) die 1112 in the middle, a high-bandwidth memory (HBM) module 1114 on the left side of the SoC die 1112, and another HBM module 1116 on the right side of the SoC die 1112. Floor plan 1110 further shows unoccupied sections 1122, 1124, 1126, and 1128. Top view 1150 of the 2.5D package shows an SoC die 1152 in the middle, an HBM module 1154 on the left side of the SoC die 1152, and another HBM module 1156 on the right side of the SoC die 1152. The placement of the dummy dies 1162, 1164, 1166, and 1168 makes the floor plan balanced and provides better protection against cracks in the package from warpage caused by stress. Advantageously, having dummy dies 1162, 1164, 1166, and 1168 with modulation of the CTE to the modulus of elasticity for these dummy dies, further reduces the warpage experienced by the 2.5D package. This in turn results in fewer failures of such 2.5D packages from the package warpage at room temperature and even at higher temperatures.

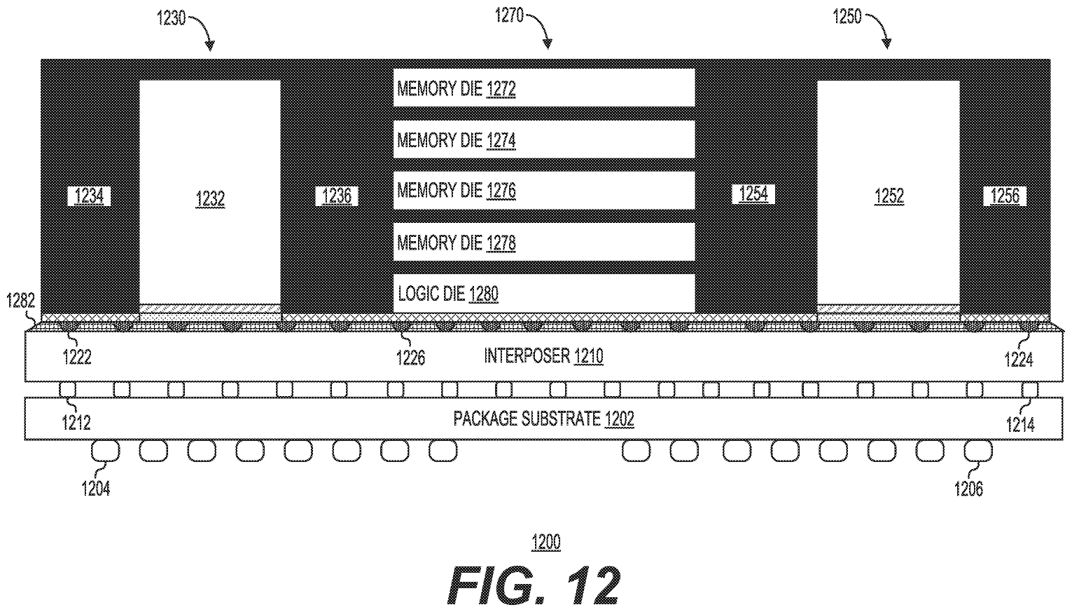

FIG. 12 shows a side view of a 2.5D package 1200 along cross-section AA of the 2.5D package of FIG. 11. Although certain components of the 2.5D package 1200, including some or all of the packaging balls and solder balls may not be visible along the cross-section AA, they are shown in FIG. 12 to show a more comprehensive view of the 2.5D package 1200. The 2.5D package 1200 includes a package substrate 1202 with packaging balls 1204 and 1206 for mounting the 2.5D package 1200 on another structure (e.g., a circuit board, not shown). The 2.5D package 1200 further includes an interposer 1210 that is mounted on top of package substrate 1202 using interconnection structures, such as Cu bumps 1212 and 1214. Dummy dies 1230 and 1250 and an HBM module 1270 are mounted on the interposer 1210 using micro-bumps 1222, 1224, and 1226. Indeed, FIG. 12 shows additional packaging balls, Cu bumps, and micro-bumps, which are not specifically identified. Any number of such structures may be formed in a manner that allows for the construction of the 2.5D packages per the examples described earlier (e.g., CoWoS). Dummy dies 1230 and 1250 and the HBM module 1270 further include underfill 1282 under them.

With continued reference to FIG. 12, both dummy dies 1230 and 1250 include a predetermined silicon to mold ratio that is selected to reduce warpage of the 2.5D package. Absent such careful selection of the silicon to mold ratio, the construction differences between conventional dummy dies (e.g., including silicon only) and the HBM modules create stress in the corners of the 2.5D package and at other places within the 2.5D package. This is because the HBM module comprises a base die (e.g., logic die 1280) and several memory (e.g., DRAM) dies (e.g., memory dies 1272, 1274, 1276, and 1278) vertically stacked on top of the base die. The memory dies (e.g., memory dies 1272, 1274, 1276, and 1278) are connected via through-silicon vias (TSVs), which are not shown. In the absence of proper silicon to mold ratio in the dummy dies, there is a higher stress in the corners of the 2.5D package due to the dummy silicon dies having a higher CTE mismatch to the substrate than the effective CTE of the HBM module, which comprises higher CTE, in combination with the mold compound and the underfill (e.g., underfill 1282).

The CTE and the modulus of elasticity for the dummy dies 1230 and 1250 is modulated by controlling the silicon to mold ratio within the respective dummy die itself. As an example, dummy die 1230 includes silicon portion 1232 and mold portions 1234 and 1236. Mold portion 1236 overlaps with the mold for the HBM module 1270. Dummy die 1250 includes silicon portion 1252 and mold portions 1254 and 1256. Mold portion 1254 overlaps with the mold for the HBM module 1270. Dummy dies can have carefully modulated CTE/modulus of elasticity by controlling the silicon to mold ratio of such dummy dies. Various examples of dummy dies with controlled silicon to mold ratio are described earlier with respect to FIG. 5 and FIG. 9. By using appropriately modulated dummy dies in this respect both warpage and cracks caused by the warpage can be minimized.

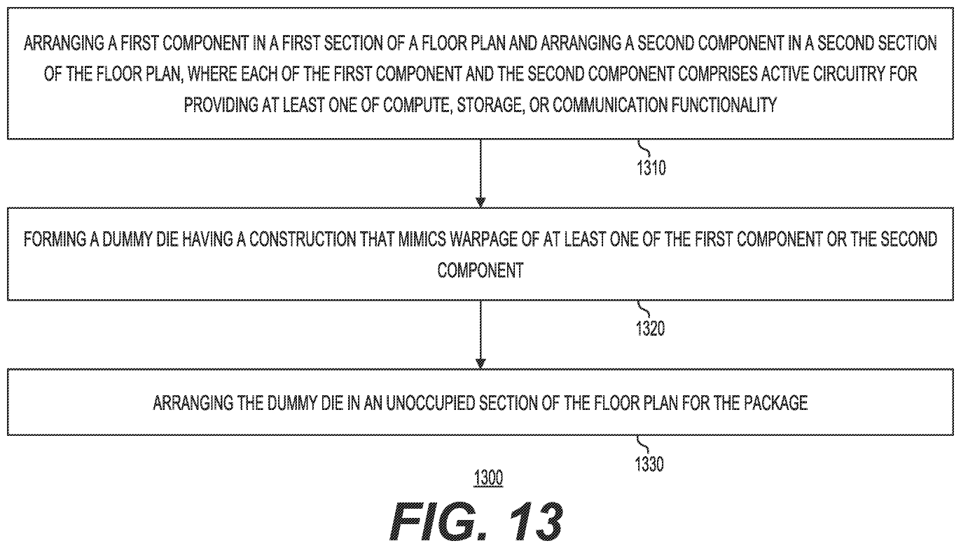

FIG. 13 shows a flow chart 1300 of a method for fabricating a package with a floor plan having sections for placement of components in accordance with one example. Step 1310 includes arranging a first component in a first section of the floor plan and arranging a second component in a second section of the floor plan, wherein each of the first component and the second component comprises active circuitry for providing at least one of compute, storage, or communication functionality. As shown with respect to FIGS. 11 and 12, the floor plan of the package can be unbalanced after the components (e.g., SoC dies or HBM modules) are placed in various sections of the floor plan.

Step 1320 includes forming a dummy die having a construction that mimics warpage of at least one of the first component or the second component. As explained earlier, in one example, step 1320 includes forming dummy dies using the process flow described with respect to FIGS. 1-4 or the process flow described with respect to FIGS. 6-9. One way to have a construction of the dummy die that mimics warpage of another component of the package is to form the dummy die with a predetermined silicon to mold ratio. As an example, FIG. 5 shows dummy die examples with different silicon to mold ratios and with having mold on only four sides or five sides of the dummy die. Another way to mimic the warpage is to ensure similar CTE and modulus of elasticity for the dummy die as the CTE and the modulus of elasticity for the other components of the package. As another example, the cross-section view in FIG. 12 shows the dummy dies included as part of a package that includes an HBM module. Depending on the number and the type of components included in the 2.5D package, the dummy dies can be constructed to mimic their warpage. This reduces the corner stress and the other stresses that the package will experience at room temperature or at a higher temperature.

With continued reference to FIG. 13, step 1330 includes arranging the dummy die in an unoccupied section of the floor plan for the package. In one example, as described earlier with respect to FIG. 11, the dummy die can be arranged in those sections of the floor plan that are not occupied by components with active circuitry. The placement of the dummy dies 1162, 1164, 1166, and 1168 makes the floor plan balanced and provides better protection against cracks in the package from warpage caused by stress. Advantageously, having dummy dies 1162, 1164, 1166, and 1168 with modulation of the CTE to the modulus of elasticity for these dummy dies, further reduces the warpage experienced by the 2.5D package. This in turn results in fewer failures of such 2.5D packages from the package warpage at room temperature and even at higher temperatures.

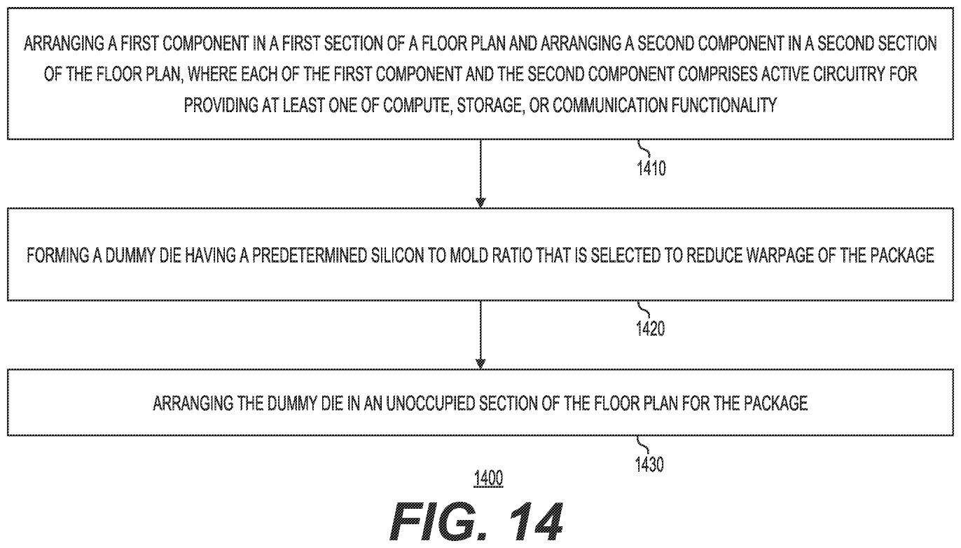

FIG. 14 shows a flow chart 1400 of a method for fabricating a package with a floor plan having sections for placement of components in accordance with one example. Step 1410 includes arranging a first component in a first section of the floor plan and arranging a second component in a second section of the floor plan, wherein each of the first component and the second component comprises active circuitry for providing at least one of compute, storage, or communication functionality. As shown with respect to FIGS. 11 and 12, the floor plan of the package can be unbalanced after the components (e.g., SoC dies or HBM modules) are placed in various sections of the floor plan.

Step 1420 includes forming a dummy die having a predetermined silicon to mold ratio that is selected to reduce warpage of the package. As explained earlier, in one example, step 1420 includes forming dummy dies using the process flow described with respect to FIGS. 1-4 or the process flow described with respect to FIGS. 6-9. As an example, FIG. 5 shows dummy die examples with different silicon to mold ratios and with having mold on only four sides or five sides of the dummy die. As another example, the cross-section view in FIG. 12 shows the dummy dies included as part of a package that includes an HBM module. Depending on the number and the type of components included in the 2.5D package, the dummy dies can be constructed appropriate silicon to mold ratios. This reduces the corner stress and the other stresses that the package will experience at room temperature or at a higher temperature.

With continued reference to FIG. 14, step 1430 includes arranging the dummy die in an unoccupied section of the floor plan for the package. In one example, as described earlier with respect to FIG. 11, the dummy die can be arranged in those sections of the floor plan that are not occupied by components with active circuitry. The placement of the dummy dies 1162, 1164, 1166, and 1168 makes the floor plan balanced and provides better protection against cracks in the package from warpage caused by stress. Advantageously, having dummy dies 1162, 1164, 1166, and 1168 with modulation of the CTE to the modulus of elasticity for these dummy dies, further reduces the warpage experienced by the 2.5D package. This in turn results in fewer failures of such 2.5D packages from the package warpage at room temperature and even at higher temperatures.

In conclusion, the present disclosure relates to a method for fabricating a package with a floor plan having sections for placement of components. The method includes arranging a first component in a first section of the floor plan and arranging a second component in a second section of the floor plan, where each of the first component and the second component comprises active circuitry for providing at least one of compute, storage, or communication functionality.

The method may further include forming a dummy die having a construction that mimics warpage of at least one of the first component or the second component. The method may further include arranging the dummy die in an unoccupied section of the floor plan for the package.

As part of this method, forming the dummy die, having the construction that mimics warpage of the at least one of the first component or the second component, may comprise forming a dummy die having a predetermined silicon to mold ratio. The forming the dummy die, having the construction that mimics warpage of the at least one of the first component or the second component, may further comprise forming a plurality of dummy silicon dies, placing the plurality of dummy silicon dies on a carrier wafer, over-molding the plurality of dummy silicon dies to form mold at least on four sides of each of the plurality of dummy silicon dies, wherein the over-molding is performed to arrive at the predetermined silicon to mold ratio, and separating the plurality of dummy silicon dies into separated dummy dies.

The first component may be at least one die or at least one chiplet and the second component may be at least one die or at least one chiplet. The package may comprise a 2.5 dimension (2.5D) package, and the warpage may be caused by a mismatch between a respective coefficient of thermal expansion and a modulus of elasticity of the dummy die and other components and material associated with the 2.5D package. The 2.5D package may comprise a third component, where each of the first component and the second component comprises a high-bandwidth memory, and where the third component comprises a system on chip (SoC).

The 2.5D package may further comprise a second dummy die, and the 2.5D package may further comprise underfill located under each of the first component, the second component, the third component, the dummy die, and the second dummy die. Each of the dummy die and the second dummy die may be arranged to make the floor plan balanced.

In another example, the present disclosure relates to a method for fabricating a package with a floor plan having sections for placement of components. The method may include arranging a first component in a first section of the floor plan and arranging a second component in a second section of the floor plan, wherein each of the first component and the second component comprises active circuitry for providing at least one of compute, storage, or communication functionality.

The method may further include forming a dummy die having a predetermined silicon to mold ratio that is selected to reduce warpage of the package. The method may further include arranging the dummy die in an unoccupied section of the floor plan for the package.

As part of this method, forming the dummy die may comprise forming a plurality of dummy silicon dies, placing the plurality of dummy silicon dies on a carrier wafer, over-molding the plurality of dummy silicon dies to form mold at least on four sides of each of the plurality of dummy silicon dies, wherein the over-molding is performed to arrive at the predetermined silicon to mold ratio, and separating the plurality of dummy silicon dies into separated dummy dies.

The package may comprise a 2.5 dimension (2.5D) package, and the warpage may be caused by a mismatch between a respective coefficient of thermal expansion and a modulus of elasticity of the dummy die and other components and material associated with the 2.5D package. Each of the first component and the second component may comprise a high-bandwidth memory (HBM) module, and each of the HBM module may comprise a logic die and a plurality of memory dies. The 2.5D package may further comprise a second dummy die, and the 2.5D package may further comprise underfill located under each of the first component, the second component, the dummy die, and the second dummy die.

In yet another example, the present disclosure relates to a 2.5 dimension (2.5D) package comprising an interposer with a floor plan for arranging components associated with the 2.5D package. The 2.5D package may further include a first component arranged in a first section of the floor plan.

The 2.5D package may further include a second component arranged in a second section of the floor plan, wherein each of the first component and the second component comprises active circuitry for providing at least one of compute, storage, or communication functionality, and wherein the first component and the second component are coupled via the interposer. The 2.5D package may further include a plurality of dummy dies, arranged in any unoccupied sections of the floor plan, where each of the plurality of dummy dies has a construction that mimics warpage of at least one of the first component or the second component.

Each of the plurality of dummy dies may have a predetermined silicon to mold ratio. The first component may be at least one die or at least one chiplet and the second component may be at least one die or at least one chiplet. The warpage may be caused by a mismatch between a respective coefficient of thermal expansion and a modulus of elasticity of the plurality of dummy dies and other components and material associated with the 2.5D package.

The 2.5D package may further comprise a third component, where each of the first component and the second component may comprise a high-bandwidth memory, and where the third component may comprise a system on chip (SoC). The 2.5D package may further comprise underfill located under each of the first component, the second component, the third component, and each of the plurality of dummy dies. Each of the plurality of dummy dies is arranged to make the floor plan balanced.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), and System-on-a-Chip systems (SOCs), Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A method for fabricating a package with a floor plan having sections for placement of components, the method comprising:
arranging a first component in a first section of the floor plan and arranging a second component in a second section of the floor plan, wherein each of the first component and the second component comprises active circuitry for providing at least one of compute, storage, or communication functionality;
forming a dummy die having a construction that mimics warpage of at least one of the first component or the second component; and
arranging the dummy die in an unoccupied section of the floor plan for the package.

2. The method of claim 1, wherein the forming the dummy die, having the construction that mimics warpage of the at least one of the first component or the second component, comprises forming a dummy die having a predetermined silicon to mold ratio.

3. The method of claim 2, wherein the forming the dummy die, having the construction that mimics warpage of the at least one of the first component or the second component, comprises:
forming a plurality of dummy silicon dies,
placing the plurality of dummy silicon dies on a carrier wafer,
over-molding the plurality of dummy silicon dies to form mold at least on two sides of each of the plurality of dummy silicon dies, wherein the over-molding is performed to arrive at the predetermined silicon to mold ratio, and
separating the plurality of dummy silicon dies into separated dummy dies.

4. The method of claim 1, wherein the first component is at least one die or at least one chiplet and wherein the second component is at least one die or a least one chiplet.

5. The method of claim 1, wherein the package comprises a 2.5 dimension (2.5D) package, and wherein the warpage is caused by a mismatch between a respective coefficient of thermal expansion and a modulus of elasticity of the dummy die and other components and material associated with the 2.5D package.

6. The method of claim 5, wherein the 2.5D package comprises a third component, wherein each of the first component and the second component comprises a high-bandwidth memory, and wherein the third component comprises a system on chip (SoC).

7. The method of claim 6, wherein the 2.5D package further comprises a second dummy die, and wherein the 2.5D package further comprises underfill located under each of the first component, the second component, the third component, the dummy die, and the second dummy die.

8. The method of claim 7, wherein each of the dummy die and the second dummy die is arranged to make the floor plan balanced.

9. A method for fabricating a package with a floor plan having sections for placement of components, the method comprising:
arranging a first component in a first section of the floor plan and arranging a second component in a second section of the floor plan, wherein each of the first component and the second component comprises active circuitry for providing at least one of compute, storage, or communication functionality;
forming a dummy die having a predetermined silicon to mold ratio that is selected to reduce warpage of the package; and
arranging the dummy die in an unoccupied section of the floor plan for the package.

10. The method of claim 9, wherein the forming the dummy die comprises:
forming a plurality of dummy silicon dies,
placing the plurality of dummy silicon dies on a carrier wafer,
over-molding the plurality of dummy silicon dies to form mold at least on two sides of each of the plurality of dummy silicon dies, wherein the over-molding is performed to arrive at the predetermined silicon to mold ratio, and
separating the plurality of dummy silicon dies into separated dummy dies.

11. The method of claim 9, wherein the package comprises a 2.5 dimension (2.5D) package, and wherein the warpage is caused by a mismatch between a respective coefficient of thermal expansion and a modulus of elasticity of the dummy die and other components and material associated with the 2.5D package.

12. The method of claim 9, wherein each of the first component and the second component comprises a high-bandwidth memory (HBM) module, and wherein each of the HBM module comprises a logic die and a plurality of memory dies.

13. The method of claim 12, wherein the 2.5D package further comprises a second dummy die, and wherein the 2.5D package further comprises underfill located under each of the first component, the second component, the dummy die, and the second dummy die.

14. A 2.5 dimension (2.5D) package comprising:
an interposer with a floor plan for arranging components;
a first component arranged in a first section of the floor plan;
a second component arranged in a second section of the floor plan, wherein each of the first component and the second component comprises active circuitry for providing at least one of compute, storage, or communication functionality, and wherein the first component and the second component are coupled via the interposer; and
a plurality of dummy dies, arranged in any unoccupied sections of the floor plan, wherein each of the plurality of dummy dies has a construction that mimics warpage of at least one of the first component or the second component.

15. The 2.5D package of claim 14, wherein each of the plurality of dummy dies has a predetermined silicon to mold ratio.

16. The 2.5D package of claim 14, wherein the first component is at least one die or at least one chiplet and wherein the second component is at least one die or a least one chiplet.

17. The 2.5D package of claim 14, wherein the warpage is caused by a mismatch between a respective coefficient of thermal expansion and a modulus of elasticity of the plurality of dummy dies and other components and material associated with the 2.5D package.

18. The 2.5D package of claim 14 further comprising a third component, wherein each of the first component and the second component comprises a high-bandwidth memory, and wherein the third component comprises a system on chip (SoC).

19. The 2.5D package of claim 18, wherein the 2.5D package further comprises underfill located under each of the first component, the second component, the third component, and each of the plurality of dummy dies.

20. The 2.5D package of claim 19, wherein each of the plurality of dummy dies is arranged to make the floor plan balanced.
